(19) United States
(12) Patent Application Publication
(10) Pub. No.: US 2010/0038705 A1
(43) Pub. Date: Feb. 18, 2010

(54) FIELD EFFECT DEVICE WITH GATE ELECTRODE EDGE ENHANCED GATE DIELECTRIC AND METHOD FOR FABRICATION

(75) Inventors: Bruce B. Doris, Brewster, NY (US); Kangguo Cheng, Guilderland, NY (US); Haining S. Yang, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 12/190,109

(22) Filed: Aug. 12, 2008

(51) Int. Cl. H01L 29/78; H01L 21/336

(52) U.S. Cl. 257/327; 438/303; 257/E29.269

(57) ABSTRACT

A semiconductor structure and a method for fabricating the semiconductor structure provide an undercut beneath a spacer that is adjacent a gate electrode within a field effect structure such as a field effect transistor structure. The undercut, which may completely or incompletely encompass the area interposed between the spacer and a semiconductor substrate is filled with a gate dielectric. The gate dielectric has a greater thickness interposed between the spacer and the semiconductor substrate than the gate and the semiconductor substrate. The semiconductor structure may be fabricated using a sequential replacement gate dielectric and gate electrode method.

### BACKGROUND

1. Field of the Invention

The invention relates generally to field effect devices. More particularly the invention relates to field effect devices with enhanced performance.

2. Description of the Related Art

Semiconductor structures include microelectronic devices that are located and formed within, upon and/or over a semiconductor substrate. The microelectronic devices are typically connected and interconnected using patterned conductor layers that are separated by dielectric layers.

Microelectronic devices may include, but are not limited to, passive devices such as but not limited to resistors and capacitors that need not necessarily be semiconductor devices. Microelectronic devices may also include, but are also not necessarily limited to, active semiconductor devices such as but not limited to diodes and transistors. Transistors, and related devices, such as but not limited to field effect transistors, have been successfully scaled for several decades to provide for continued advances in semiconductor circuit performance and semiconductor circuit functionality.

One of the recent advances that has been implemented in an effort to continue to provide for semiconductor circuit performance enhancement and semiconductor device performance enhancement is the use within field effect devices of gate stacks that include: (1) a gate dielectric that comprises a comparatively high dielectric constant (i.e., greater than about 7) gate dielectric material; and (2) a gate that comprises a metal (i.e., base metal, metal alloy or metal nitride) gate material. Such gate stacks are desirable insofar as: (1) generally higher dielectric constant gate dielectric materials allow for thicker gate dielectrics that provide for avoidance of thinner gate dielectric based defects; and (2) metal gate materials allow for engineering of a work function of a particular gate, to provide for performance enhancement of a particular field effect device into which is fabricated the work function engineered metal gate.

While gate dielectrics that comprise comparatively high dielectric constant gate dielectric materials and metal gates that comprise metal gate materials are thus desirable within the semiconductor fabrication art, gate dielectrics that comprise comparatively high dielectric gate dielectric materials and metal gates that comprise metal gate materials are nonetheless not entirely without problems in the semiconductor fabrication art for fabricating enhanced field effect devices. In particular, while comparatively higher dielectric constant gate dielectric materials are desirable for gate dielectrics when fabricating advanced field effect devices, comparatively higher dielectric constant gate dielectric materials are nonetheless also potentially susceptible to defects in integrity, particularly at gate edges, such as metal gate edges.

Various semiconductor structures, including field effect device structures, having desirable properties, as well as methods for fabricating those semiconductor structures, are known in the semiconductor fabrication art.

For example, Hareland in U.S. Pat. No. 6,864,145 and U.S. Pat. No. 7,078,750 teaches a field effect structure fabricated using a replacement gate and a replacement gate dielectric method that provides for enhanced reliability and reduced gate edge leakage of a field effect device fabricated within the field effect structure. The foregoing result is realized by selectively treating edge portions of a replacement gate dielectric within a replacement gate aperture within the field effect structure prior to forming a replacement gate within the replacement gate aperture.

Semiconductor structure and semiconductor device dimensions are certain to continue to decrease, and semiconductor circuit performance requirements are certain to continue to increase, as semiconductor technology advances. Since gate stacks comprising gate dielectrics that include comparatively high dielectric constant gate dielectric materials and metal gates that comprise metal gate materials have become integral to semiconductor device performance enhancements, desirable are additional methods and materials that provide for optimization of semiconductor structures and semiconductor devices that include gate dielectrics that include comparatively high dielectric constant gate dielectric materials and metal gates that comprise metal gate materials.

### SUMMARY OF THE INVENTION

The invention provides a semiconductor structure that includes a field effect structure, and a method for fabricating the semiconductor structure that includes the field effect structure. The particular semiconductor structure and method provide that both a gate, and at least in-part a spacer, are located upon a gate dielectric that is located upon a semiconductor substrate. Within the particular semiconductor structure, a thickness of the gate dielectric interposed between the spacer and the semiconductor substrate is greater than a thickness of the gate dielectric interposed between the gate and the semiconductor substrate. The invention contemplates a replacement gate and replacement gate dielectric method for fabricating the semiconductor structure that includes the field effect structure, and to that end the greater thickness of the gate dielectric interposed between the spacer and the semiconductor substrate in comparison with the gate and the semiconductor substrate provides for enhanced performance of a field effect device within the field effect structure due to reduced possibility of gate electrode edge leakage within such a replacement gate and replacement gate dielectric method.

A particular semiconductor structure in accordance with the invention includes a semiconductor substrate. The semiconductor structure also includes a gate dielectric located upon the semiconductor substrate. The semiconductor structure also includes a gate electrode located upon the gate dielectric and over a channel region within the semiconductor substrate. The semiconductor structure also includes a spacer located adjacent a sidewall of the gate electrode and also at least in-part upon the gate dielectric. The semiconductor structure also includes a plurality of source and drain regions located within the semiconductor substrate and separated by the channel. Within the semiconductor structure, a portion of the gate dielectric interposed between the spacer and the semiconductor substrate is thicker than a portion of the gate dielectric interposed between the gate electrode and the semiconductor substrate.

Another particular semiconductor structure in accordance with the invention includes a semiconductor substrate. This other particular semiconductor structure also includes a gate dielectric having a dielectric constant greater than about 7 located upon the semiconductor substrate. This other particular semiconductor structure also includes a gate electrode comprising a metal gate material located upon the gate dielectric and over a channel region within the semiconductor substrate. This other particular semiconductor structure also includes a spacer located adjacent a sidewall of the gate electrode and also at least in-part upon the gate dielectric. This other particular semiconductor structure also includes a plurality of source and drain regions located within the semiconductor substrate and separated by the channel. Within this other particular semiconductor structure, a portion or the gate dielectric interposed between the spacer and the semiconductor substrate is thicker than a portion of the gate dielectric interposed between the gate and the semiconductor substrate.

A particular method for fabricating a semiconductor structure in accordance with the invention includes providing a semiconductor structure including: (1) a semiconductor substrate; (2) a dummy gate dielectric located upon the semiconductor substrate; (3) a dummy gate electrode located upon the dummy gate dielectric and over a channel region within the semiconductor substrate; (4) a spacer located adjacent a sidewall of the dummy gate electrode and also at least in-part upon the dummy gate dielectric; and (5) a plurality of source and drain regions located within the semiconductor substrate and separated by the channel. This particular method also includes etching the dummy gate from the semiconductor structure to expose the dummy gate dielectric. This particular method also includes etching the dummy gate dielectric to expose the channel region and form a void at least in-part undercut beneath the spacer. This particular method also includes forming a gate dielectric upon the channel region and filling the void. This particular method also includes forming a gate electrode upon the gate dielectric.

### BRIEF DESCRIPTION OF THE DRAWINGS

The objects, features and advantages of the invention are understood within the context of the Description of the Preferred Embodiments, as set forth below. The Description of the Preferred Embodiments is understood within the context of the accompanying drawings, that form a material part of this disclosure, wherein:

FIG. 1 to FIG. 6 show a series of schematic cross sectional diagrams illustrating the results of progressive field effect structure fabrication (FIG. 1 and FIG. 2), dummy gate stripping (FIG. 3), dummy gate dielectric stripping (FIG. 4), gate dielectric backfill (FIG. 5) and gate backfill (FIG. 6) process steps in accordance with a particular embodiment of the invention.

FIG. 7 to FIG. 12 show a series of schematic cross sectional diagrams illustrating the results of progressive field effect structure fabrication (FIG. 7 and FIG. 8), dummy gate stripping (FIG. 9), dummy gate dielectric stripping (FIG. 10), gate dielectric backfill (FIG. 11) and gate backfill (FIG. 12) process steps in accordance with another particular embodiment of the invention.

### DESCRIPTION OF THE PREFERRED EMBODIMENTS

The invention, which includes a semiconductor structure that includes a field effect structure having enhanced performance due to reduced gate electrode edge leakage within the context of a replacement gate and replacement gate dielectric method, is understood within the context of the description set forth below. The description set forth below is understood within the context of the drawings described above. Since the drawings are intended for illustrative purposes, the drawings are not necessarily drawn to scale.

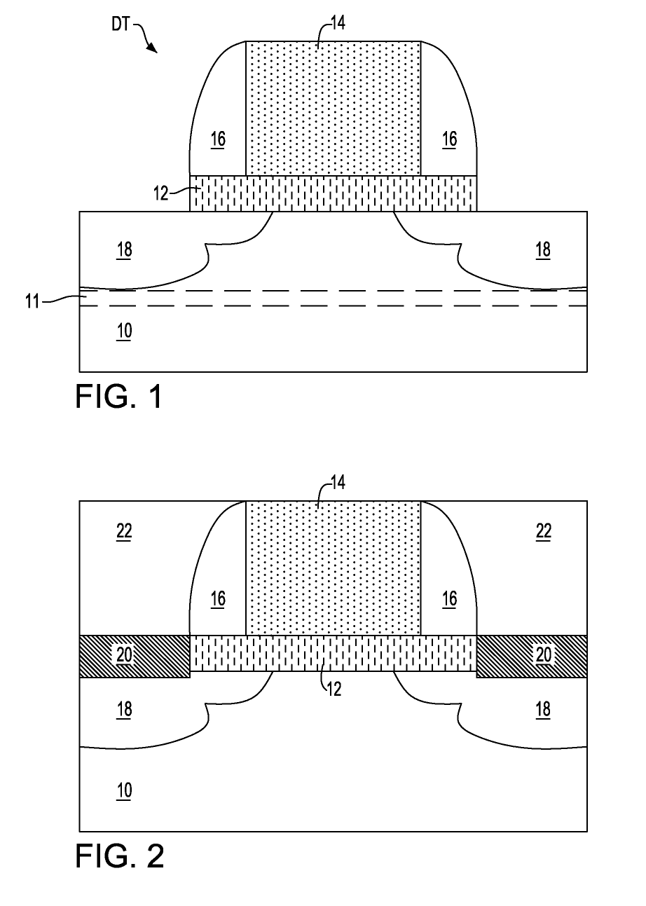

FIG. 1 to FIG. 6 show a series of schematic cross-sectional diagrams illustrating the results of progressive field effect device fabrication, dummy gate stripping, dummy gate dielectric stripping, gate dielectric backfill and gate electrode backfill process steps for fabricating a semiconductor structure in accordance with a particular embodiment of the invention. This particular embodiment of the invention comprises a first embodiment of the invention. FIG. 1 shows a schematic cross-sectional diagram of the semiconductor structure at an early stage in the fabrication thereof in accordance with this particular first embodiment of the invention.

FIG. 1 shows a semiconductor substrate 10 within and upon which is fabricated a dummy transistor DT in accordance with this particular embodiment.

The semiconductor substrate 10 may comprise one or more semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials. Typically, the semiconductor substrate comprises a silicon or silicon-germanium alloy semiconductor material.

While FIG. 1 illustrates the invention within the context of a bulk semiconductor substrate for the semiconductor substrate 10, neither the embodiment, nor the invention, is intended to be so limited. Rather, the embodiment and the invention also contemplate as an alternative of a bulk semiconductor substrate for the semiconductor substrate 10 a semiconductor-on-insulator (SOI) substrate or a hybrid orientation (HOT) substrate.

A semiconductor-on-insulator substrate includes a buried dielectric layer 11 (illustrated in phantom within FIG. 1) interposed between a base semiconductor substrate portion of the semiconductor substrate 10 and a surface semiconductor layer portion of the semiconductor substrate 10.

The buried dielectric layer 11 may comprise one or more dielectric materials. Non-limiting examples include oxides, nitrides and oxynitrides, particularly of silicon, but oxides, nitrides and oxynitrides of other elements are not excluded. The buried dielectric layer 11 may comprise a crystalline or a non-crystalline dielectric material, with crystalline dielectrics being highly preferred. The buried dielectric layer 11 may be formed using one or more methods. Non-limiting examples include ion implantation methods, thermal or plasma oxidation or nitridation methods, chemical vapor deposition methods and physical vapor deposition methods. Typically, the buried dielectric layer 11 comprises an oxide of the semiconductor material from which is comprised the semiconductor substrate 10. Typically, a buried dielectric layer within a semiconductor-on-insulator substrate has a thickness from about 10 to about 300 nanometers, although a lesser or greater thickness is also explicitly contemplated herein.

Within a semiconductor-on-insulator substrate, a surface semiconductor layer may comprise any of the several semiconductor materials from which a base semiconductor substrate may be comprised. The surface semiconductor layer and the base semiconductor substrate may comprise either identical or different semiconductor materials with respect to chemical composition, dopant concentration and crystallographic orientation. Typically, a surface semiconductor layer within a semiconductor-on-insulator substrate has a thickness from about 3 to about 100 nanometers, although a lesser or greater thickness is also explicitly contemplated herein.

A hybrid orientation substrate includes multiple regions of different crystallographic orientation.

Semiconductor-on-insulator substrates and hybrid orientation substrates may be fabricated using methods including but not limited to layer transfer methods, layer lamination methods and separation by implantation of oxygen methods.

The dummy transistor DT that is illustrated in FIG. 1 comprises: (1) a dummy gate dielectric 12 located upon the semiconductor substrate 10; (2) a dummy gate electrode 14 located upon the dummy gate dielectric 12; (3) a spacer 16 located adjoining sidewalls of the dummy gate electrode 14 and also located completely upon the dummy gate dielectric 12; and (5) a plurality of source and drain regions 18 located within the semiconductor substrate 10 and separated by a channel region beneath the dummy gate electrode 14.

Each of the foregoing layers and structures may comprise materials and have dimensions that are conventional in the semiconductor fabrication art. Each of the foregoing layers and structures may also be formed using methods that are conventional in the semiconductor fabrication art.

The dummy gate dielectric 12 may in general comprise one or more sacrificial materials that need not necessarily comprise gate dielectric materials. Such sacrificial materials may include, but are not necessarily limited to, conductor materials, semiconductor materials and dielectric materials. Most typically, the dummy gate dielectric 12 comprise a dielectric material that is otherwise generally conventional, such as but not limited to a silicon oxide material, a silicon nitride material or a silicon oxynitride material. Most typically, the dummy gate dielectric 12 comprises a silicon oxide material formed using a thermal oxidation method, under circumstances where the semiconductor substrate 10 comprises a silicon semiconductor material. Typically, and for reasons that will become clearer within the context of further description below, the dummy gate dielectric 12 is thicker (i.e., but no greater than twice as thick) than a gate dielectric desired to be formed within the context of further processing of the semiconductor structure of FIG. 1. Typically, the dummy gate dielectric 12 has a thickness from about 3 to about 20 nanometers, although a lesser or greater thickness is also explicitly contemplated herein.

The dummy gate 14 may comprise one or more materials that have an appropriate etch selectivity with respect to surrounding materials, also within the context of further processing of the semiconductor structure whose schematic cross-sectional diagram is illustrated in FIG. 1. Such materials may include, but are not necessarily limited to conductor materials, semiconductor materials and dielectric materials. While by no means limiting the embodiment or the invention, the dummy gate 14 typically comprises a polycrystalline silicon (polysilicon) or polycrystalline silicon-germanium alloy material. Such a polysilicon or polysilicon-germanium alloy material may typically be formed using a chemical vapor deposition method or a physical vapor deposition method, although such deposition methods also do not limit the invention. Typically, the dummy gate has a thickness from about 20 to about 150 nanometers, although a lesser or greater thickness is also explicitly contemplated herein.

The spacer 16 (which while illustrated as plural components in cross-section is actually intended as a single layer encircling the dummy gate 14 in plan-view) may comprise materials including, but not limited to conductor materials and dielectric materials. Conductor spacer materials are less common, but are nonetheless known. Dielectric spacer materials are more common. The spacer materials may be formed using methods analogous, equivalent or identical to the methods that are used for forming the dummy gate dielectric 12, when the dummy gate dielectric 12 comprises a dielectric material. The spacer 16 is also formed with the distinctive inward pointing spacer shape by using a blanket layer deposition and anisotropic etchback method. The spacer 16 may comprise a single layer or a plurality of layers of materials. Typically, the spacer 16 comprises a silicon nitride material when the dummy gate dielectric 12 comprises a silicon oxide dielectric material, although this particular materials combination does not limit the embodiment or the invention. Similarly, while FIG. 1 illustrates the spacer 16 as located completely upon the dummy gate dielectric 12, an operative embodiment may also under certain circumstances be realized when the spacer 16 is located in-part upon the dummy gate dielectric 12.

Finally, the plurality of source and drain regions 18 comprises a generally conventional dopant whose polarity is consistent with the polarity of a field effect transistor desired to be fabricated incident to further processing of the dummy transistor DT that is illustrated in FIG. 1. As is understood by a person skilled in the art, the plurality of source and drain regions 18 is formed using a two step ion implantation method. A first ion implantation process step within the method uses the dummy gate 14, absent the spacer 16 (in the case that the spacer 16 comprises a single layer of material or a portion of the spacer 16 in the case that the spacer 16 comprises multiple layers of materials), as a mask to form a plurality of extension regions each of which extends beneath the spacer 16. A second ion implantation process step uses the dummy gate 14 and the entire spacer 16 as a mask to form the larger contact region portions of the plurality of source and drain regions 18, while simultaneously incorporating the plurality of extension regions. Dopant levels are from about 1×10¹⁹ to about 5×10²¹ dopant atoms per cubic centimeter within each of the plurality of source and drain regions 18. Extension regions within the plurality of source and drain regions 18 may under certain circumstances be more lightly doped than contact regions with the plurality of source and drain regions, although such differential doping concentrations are not a requirement of the embodiment.

FIG. 2 first shows a plurality of silicide layers 20 located and formed upon portions of the plurality of source and drain regions 18 exposed adjacent the dummy gate dielectric 12. Depending on a surface layer composition of dummy gate 14, a silicide layer may also be formed on top of the dummy gate 14 (i.e., under circumstances where the dummy gate 14 comprises a polysilicon material a silicide layer is formed upon the dummy gate 14, or alternatively no silicide layer is formed on top of the dummy gate 14 under the circumstances where the dummy gate 14 comprises a dielectric material). The foregoing silicide layer 20 may comprise one or more silicide forming metals. Non-limiting examples of candidate silicide forming metals include nickel, cobalt, titanium, tungsten, erbium, ytterbium, platinum, and vanadium silicide forming metals. Nickel and cobalt silicide forming metals are particularly common. Others of the above enumerated silicide forming metals are less common. Typically, the silicide layers 20 are formed using a salicide method. The salicide method includes: (1) forming a blanket silicide forming metal layer upon the semiconductor structure of FIG. 1; (2) thermally annealing the blanket silicide forming metal layer with silicon surfaces which it contacts to selectively form the silicide layers 20 while leaving unreacted metal silicide forming metal layers on, for example, the spacer 16; and (3) selectively stripping unreacted portions of the silicide forming metal layers from, for example, the spacer 16. Typically, the silicide layers 20 comprise a nickel silicide material or a cobalt silicide material that has a thickness from about 5 to about 30 nanometers, although a lesser or greater thickness is also explicitly contemplated herein.

FIG. 2 also shows an inter-level dielectric 22 located and formed upon the silicide layers 20, and adjacent and adjoining the spacer 16, while simultaneously being planarized to the level of the dummy gate 14.

The inter-level dielectric 22 may comprise one or more inter-level dielectric materials. Such inter-level dielectric materials may comprise generally conventional inter-level dielectric materials, such as but not limited to oxides, nitrides and oxynitrides of silicon that have a generally higher dielectric constant from about 4 to about 10. This particular embodiment also however contemplates that the inter-level dielectric 22 may comprise, but is also not necessarily limited to, a generally lower dielectric constant inter-level dielectric material that has a dielectric constant from about 1.5 to about 4.0. Such generally lower dielectric constant inter-level dielectric materials may include, but are not limited to spin-on-glass dielectric materials, spin-on-polymer dielectric materials, fluorosilicate glass dielectric materials and nanoporous dielectric materials. Typically, the inter-level dielectric 22 comprises at least in-part a lower dielectric constant dielectric material that has dielectric constant from about 1.5 to about 4.

The inter-level dielectric 22 is typically first deposited as a blanket inter-level dielectric and subsequently planarized to form the inter-level dielectric 22. Such planarization may be effected using methods including but not limited to mechanical planarizing methods, and chemical mechanical polish planarizing methods.

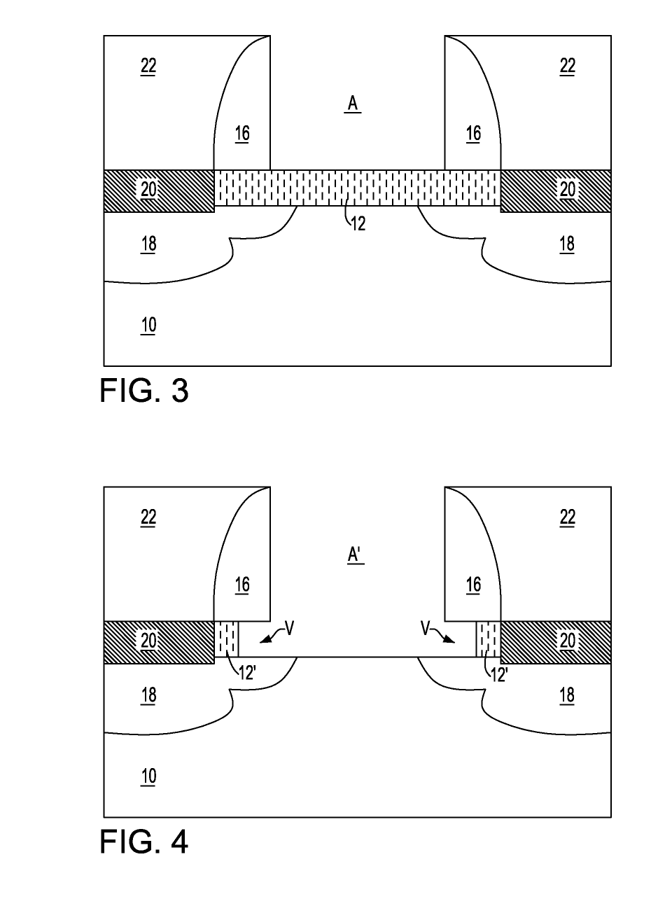

FIG. 3 shows the results of stripping the dummy gate 14 from the semiconductor structure of FIG. 2 to leave an aperture A that exposes the dummy gate dielectric 12.

The dummy gate 14 may be stripped from the semiconductor structure of FIG. 2 to provide the aperture A that exposes the dummy gate dielectric 12 within the semiconductor structure of FIG. 3 while using etch methods that use etch materials that are appropriate to the material from which is comprised the dummy gate 14. Such etch methods and etch materials may include, but are not necessarily limited to, wet chemical etch methods and materials, dry plasma etch methods and materials, and combinations of combinations of wet chemical etch methods and materials and dry plasma etch methods and materials.

FIG. 4 shows the results of etching the dummy gate dielectric 12 to an undercut distance about ½ the base linewidth of the spacer 16 (i.e., from about 2 to about 10 nanometers, although a lesser or greater thickness is also explicitly contemplated herein.) to form an enlarged aperture A′ (i.e., including undercut voids V) from the aperture A that is illustrated in FIG. 3 and a dummy gate dielectric 12′ from the gate dielectric 12 that is illustrated in FIG. 3. The enlarged aperture A′ is in the shape of an inverted “T”. Similarly with the dummy gate 14, the dummy gate dielectric 12 may also be etched using methods and materials that are appropriate to the material from which is comprised the dummy gate dielectric 12. Such methods may also include, but are also not necessarily limited to wet chemical etch methods and materials, dry plasma etch methods and materials and combinations of wet chemical etch methods and materials and dry plasma etch methods and materials. When the dummy gate dielectric 12 comprises a silicon oxide material, the dummy gate dielectric 12 may be effectively etched using an aqueous hydrofluoric acid etchant to provide the dummy gate dielectric 12′.

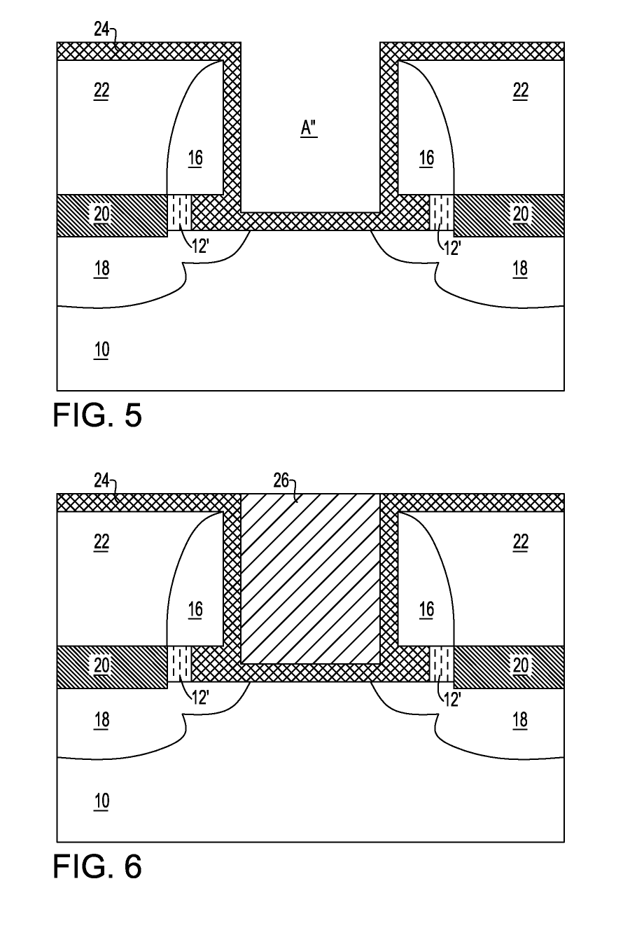

FIG. 5 shows a gate dielectric 24 located and formed into the aperture A′ that is illustrated in FIG. 4, and in particular filling the undercut voids V interposed between the spacer 16 and the semiconductor substrate 10, thus forming from the aperture A′ an aperture A″. As is illustrated in FIG. 5, the gate dielectric 24 abuts the dummy gate dielectric 12′.

The gate dielectric 24 may comprise conventional dielectric materials such as oxides, nitrides and oxynitrides of silicon that have a dielectric constant from about 4 to about 7, measured in vacuum. Alternatively, and preferably, the gate dielectric 24 may comprise generally higher dielectric constant dielectric materials having a dielectric constant from about 7 (or alternatively from about 20) to at least about 100. Such higher dielectric constant dielectric materials may include, but are not limited to hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate or any combination of these materials. The gate dielectric 24 may be formed using one or more methods that are appropriate to its material of composition. Included, but not limiting are thermal, chemical, or plasma oxidation or nitridation methods, atomic layer deposition methods, chemical vapor deposition methods and physical vapor deposition methods. Typically, the gate dielectric 24 comprises a higher dielectric constant dielectric material, such as but not limited to a hafnium oxide dielectric material or a hafnium silicate dielectric material. More typically, the gate dielectric 24 comprises a higher dielectric constant dielectric material (e.g., but not limited to, a hafnium oxide dielectric material or a hafnium silicate dielectric material), and an interfacial layer (e.g., but not limited to, chemical oxide, plasma oxide, plasma nitride, plasma oxynitride, or any combination of those materials) between the higher dielectric constant dielectric material and the semiconductor substrate 10.

As is illustrated within the schematic cross-sectional diagram of FIG. 5, the gate dielectric 24 is formed as a conformal layer that covers all exposed surfaces of the semiconductor structure of FIG. 5. Thus, in order to fill the undercut voids V that are illustrated within the schematic cross-sectional diagram of FIG. 4 a thickness of the gate dielectric 24 must be greater than half the thickness of the dummy gate dielectric 12′. Desirably, the thickness of the gate dielectric 24 is also less than the thickness of the dummy gate dielectric 12′. Typically, the gate dielectric 24 has a thickness from about 2 to about 10 nanometers (alternatively from about 2 to about 15 nanometers), although a lesser or greater thickness is also explicitly contemplated herein.

FIG. 6 shows a gate 26 (i.e., a gate electrode) located and formed planarized into the aperture A″ that is illustrated in FIG. 5. The gate 26 may in general comprise one or more gate conductor materials. Such gate conductor materials may include, but are not necessarily limited to certain metals, metal alloys, metal silicide and metal nitride gate materials. Also included are doped polysilicon materials and polycide materials. The gate 26 may be formed by deposition methods followed by planarization methods that are appropriate to its material of composition. Included, but not limiting, as deposition methods are atomic layer deposition methods, chemical vapor deposition methods physical vapor deposition methods, plating methods, as well as any combination of those methods. Included, but not limiting, as planarization methods are chemical mechanical polishing and electrochemical mechanical polishing. Within the context of the instant embodiment, the gate 26 preferably comprises a metal gate material, such as but not limited to a metal nitride whose work function may be appropriately adjusted to effect desirable performance characteristics of the field effect transistor whose schematic cross-sectional diagram is illustrated in FIG. 6. Typical metal nitride gate materials may include, but are not necessarily limited to, titanium nitride materials and tantalum nitride materials. Alternatively, the gate 26 may comprise other conducting materials, including but not limited to, Zr, W, Ta, Hf, Ti, Al, Co, Ru, Pd, Pt, Co, Ni, metal oxide, metal carbide, metal nitride (e.g., Mo2N) and transition metal aluminide materials (e.g. Ti₃Al, ZrAl), as well as TaC, TaMgC, TiAlN, WCN, Mo₂N and MoAlN materials.

FIG. 6 shows a schematic cross-sectional diagram of a semiconductor structure in accordance with a particular embodiment of the invention that comprises a first embodiment of the invention. The semiconductor structure includes a field effect structure, and in particular a field effect transistor structure. Within the semiconductor structure that includes the field effect transistor structure, and in a first instance, a portion of the gate dielectric 24 is located within a void area interposed between the spacer 16 and the semiconductor substrate 10. This particular portion of the gate dielectric 24 is thicker (i.e., having a thickness from about 3 to about 20 nanometers) than a portion of the gate dielectric located interposed between the gate 26 and the semiconductor substrate 10 (i.e., having a thickness from about 2 to about 10 nanometers). Such an increased thickness of the gate dielectric 24, which is at the gate 26 edge, is desirable within the embodiment and the invention insofar as such a thickness at the gate 26 edge provides for a reduction of gate dielectric defects at the gate 26 edge.

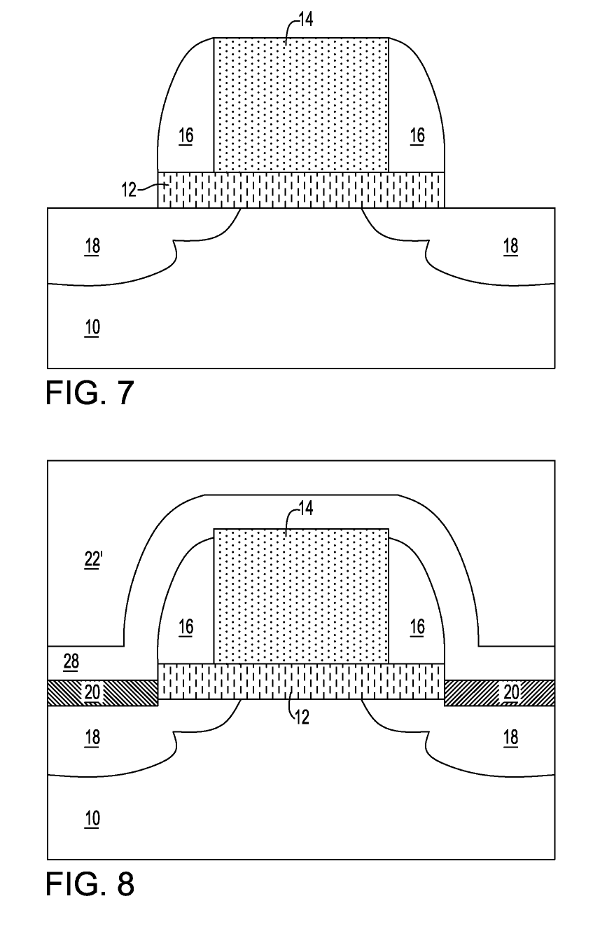

FIG. 7 to FIG. 12 show a series of schematic cross-sectional diagrams illustrating the results of progressive stages in fabricating a semiconductor structure in accordance with another embodiment of the invention. This other embodiment of the invention comprises a second embodiment of the invention. FIG. 7 shows a schematic cross-sectional diagram of the semiconductor structure at an early stage in the fabrication thereof in accordance with this other second embodiment.

FIG. 7 shows a schematic cross-sectional diagram of a semiconductor structure that corresponds with the semiconductor structure whose schematic cross-sectional diagram is illustrated in FIG. 1. Like and/or identical structural elements are designated using identical reference numerals within FIG. 1 and FIG. 7.

FIG. 8 shows a schematic cross-sectional diagram that corresponds with the schematic cross-sectional diagram of FIG. 2, but with: (1) the addition of a liner 28; and (2) also the presence of an unplanarized inter-level dielectric 22′ rather than the planarized inter-level dielectric 22 that is illustrated in FIG. 2. The inter-level dielectric 22′ comprises materials, and may be formed using methods, that are analogous, equivalent or identical to the materials and methods that are used for forming the inter-level dielectric 22 that is illustrated in FIG. 2. The liner 28 may comprise one or more liner materials that are intended to serve one or more liner purposes. Etch stop liner purposes are generally common, although such etch stop purposes by no means limits the embodiment or the invention. Mechanically stressed liners are also known. Typically, the liner 28 comprises a silicon nitride material that may be adjusted for stress introduction purposes within the semiconductor structure whose schematic cross-sectional diagram is illustrated in FIG. 8, as well as etch stop purposes within the semiconductor structure whose schematic cross-sectional diagram is illustrated in FIG. 8. Typically, such a silicon nitride material may be formed using methods including but not limited to chemical vapor deposition methods and physical vapor deposition methods. Chemical vapor deposition methods are generally more common. Typically, the liner 28 is formed to a non-limiting thickness from about 10 to about 100 nanometers.

While FIG. 8 illustrates the liner 28 as a potential mechanically stressed component within the semiconductor structure of FIG. 8, neither the embodiment nor the invention is intended to be so limited. Rather, all embodiments of the invention also contemplate other components (i.e., within, upon or above the semiconductor substrate 10) within a field effect structure may serve as stress inducing components. Such mechanical stress may be compressive, tensile or a combination of compressive and tensile. As well, such stress may be uniaxial as well as multiaxial.

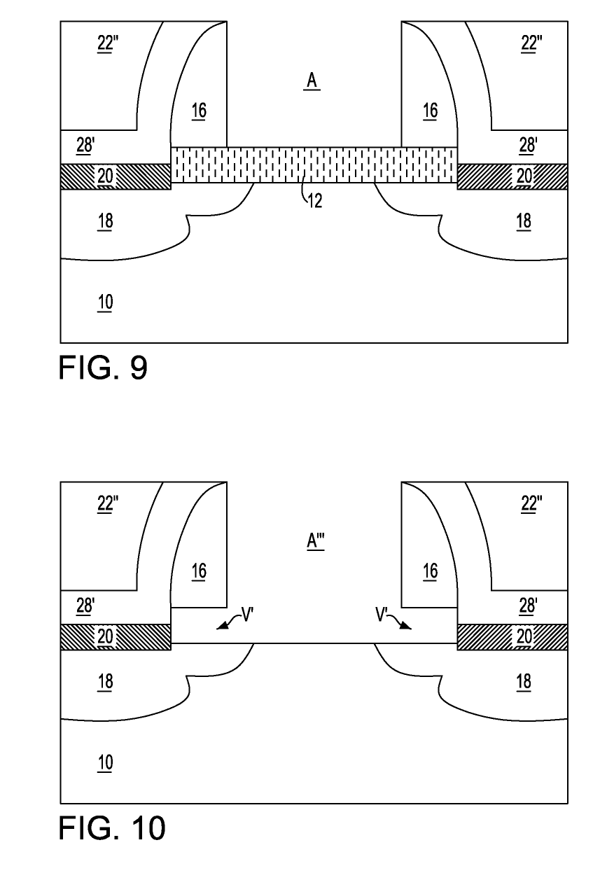

FIG. 9 corresponds generally with FIG. 3, but first includes a planarizing process step that provides: (1) that the inter-level dielectric 22′ is planarized to the level of the dummy gate 14 to provide an inter-level dielectric 22″; and (2) the liner 28 is planarized to the level of the dummy gate 14 to form a liner 28′; prior to (3) stripping the dummy gate 14 from the resulting structure to provide the aperture A that exposes the dummy gate dielectric 12 that is illustrated in FIG. 9. Similarly with the inter-level dielectric 22 that is illustrated in FIG. 2, such planarizing is effected using planarizing methods and planarizing materials that are otherwise generally conventional in the semiconductor fabrication art. Included in particular, but also not limiting, are mechanical planarizing methods and chemical mechanical polish planarizing methods.

Subsequent to planarizing the inter-level dielectric 22′ to form the inter-level dielectric 22″ and planarizing the liner 28 to form the liner 28′, the dummy gate 14 may be stripped to provide the semiconductor structure whose schematic cross-sectional diagram is illustrated in FIG. 9. The dummy gate 14 may be stripped while using methods and materials that are analogous, equivalent or identical to the methods and materials that are used for stripping the dummy gate 14 that is illustrated within the semiconductor structure whose schematic cross-sectional diagram is illustrated in FIG. 2 to provide the semiconductor structure whose schematic cross-sectional diagram is illustrated in FIG. 3.

FIG. 10 corresponds generally with FIG. 4, but instead illustrates a complete stripping of the dummy gate dielectric 12 from beneath the spacer 16 to provide an aperture A′″ that includes extended voids V′. As is illustrated in FIG. 10, the liner 28′ and the silicide layers 20 serve as an etch stop when completely stripping the dummy gate dielectric 12 from the semiconductor structure whose schematic cross-sectional diagram is illustrated in FIG. 9 when fabricating the semiconductor structure whose schematic cross-sectional diagram is illustrated in FIG. 10.

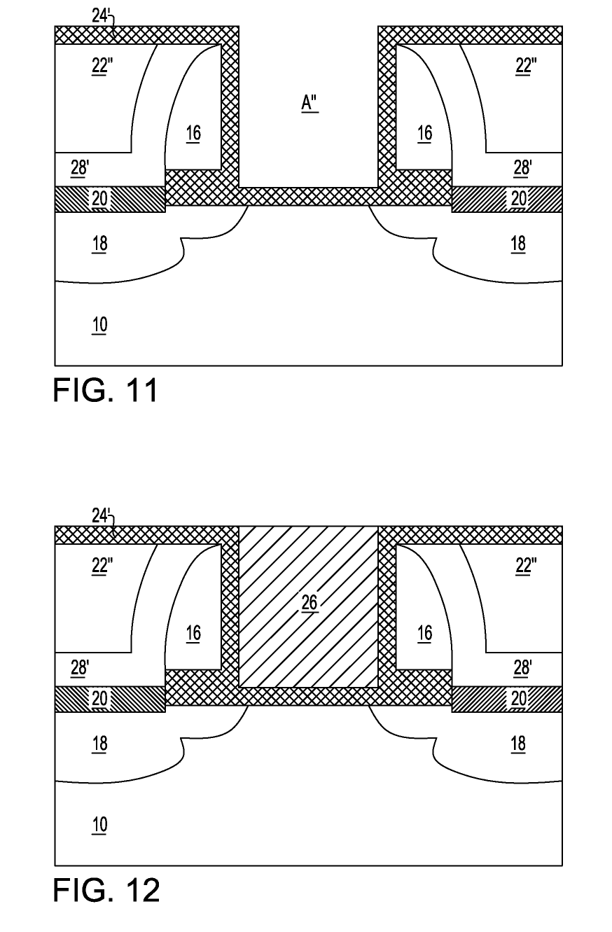

FIG. 11 corresponds generally with FIG. 5, but shows a gate dielectric 24′ that completely fills and supports an entire area interposed between the spacer 16 and the semiconductor substrate 10, rather than partially filling the area interposed between the spacer 16 and the semiconductor substrate 10. Otherwise, the aperture A″ that is illustrated within the schematic cross-sectional diagram of FIG. 1 corresponds with the aperture A″ that is illustrated within the schematic cross-sectional diagram of FIG. 5.

FIG. 12 corresponds with FIG. 6 and illustrates the same gate 26 located and formed into the aperture A″ that is illustrated in FIG. 11.

FIG. 12 shows a schematic cross-sectional diagram of a semiconductor structure in accordance with another embodiment of the invention that comprises a second embodiment of the invention. In a first instance, this particular semiconductor structure differs from the semiconductor structure of FIG. 6 with respect to the presence of a liner layer 28′. As discussed above, the liner 28′ serves at least in-part to provide etch stop properties when fabricating the semiconductor structure whose schematic cross-sectional diagram is illustrated in FIG. 12. In a second instance, this particular semiconductor structure differs from the semiconductor structure of FIG. 6 insofar as the gate dielectric 24′, in addition to having a greater thickness interposed between the spacer 16 and the semiconductor substrate 10 in comparison with a thickness between the gate 26 and the semiconductor substrate 10, is also formed completely underneath the spacer 16 rather than only partially underneath the spacer 16. The semiconductor structure whose schematic cross-sectional diagram is illustrated in FIG. 12 otherwise possesses all of the remaining advantages of the semiconductor structure whose schematic cross-sectional diagram is illustrated in FIG. 6.

The foregoing preferred embodiments are illustrative of the invention rather than limiting of the invention. Revisions and modifications may be made to methods, materials sub-structures and dimensions of a semiconductor structure in accordance with the preferred embodiments, while still providing a semiconductor structure and a method for fabrication thereof in accordance with the invention, further in accordance with the accompanying claims.

What is claimed is:

1. A semiconductor structure comprising:
a semiconductor substrate;
a gate dielectric located upon the semiconductor substrate;
a gate electrode located upon the gate dielectric and over a channel region within the semiconductor substrate;
a spacer located adjacent a sidewall of the gate electrode and also at least in-part upon the gate dielectric; and
a plurality of source and drain regions located within the semiconductor substrate and separated by the channel, where a portion of the gate dielectric interposed between the spacer and the semiconductor substrate is thicker than a portion of the gate dielectric interposed between the gate electrode and the semiconductor substrate.

2. The semiconductor structure of claim 1 wherein the semiconductor substrate comprises a bulk semiconductor substrate.

3. The semiconductor structure of claim 1 wherein the semiconductor substrate comprises a semiconductor-on-insulator substrate.

4. The semiconductor structure of claim 1 wherein the semiconductor substrate comprises a hybrid orientation substrate.

5. The semiconductor structure of claim 1 wherein the gate dielectric has a dielectric constant less than about 7.

6. The semiconductor structure of claim 1 wherein the gate dielectric has a dielectric constant greater than about 7.

7. The semiconductor structure of claim 1 wherein the gate electrode comprises a metal material.

8. The semiconductor structure of claim 1 wherein the spacer is located completely upon the gate dielectric.

9. The semiconductor structure of claim 1 wherein the spacer is also located upon an additional layer that laterally abuts the gate dielectric.

10. The semiconductor structure of claim 1 wherein the thickness of the gate dielectric between the spacer and the semiconductor substrate is from about 3 to about 20 nanometers and the thickness of the gate dielectric between the gate and the semiconductor substrate is from about 2 to about 10 nanometers.

11. The semiconductor structure of claim 1 wherein the gate dielectric is also located interposed between the gate electrode and the spacer.

12. A semiconductor structure comprising:
a semiconductor substrate;
a gate dielectric having a dielectric constant greater than about 7 located upon the semiconductor substrate;
a gate electrode comprising a metal gate material located upon the gate dielectric and over a channel region within the semiconductor substrate;
a spacer located adjacent a sidewall of the gate electrode and also at least in-part upon the gate dielectric; and
a plurality of source and drain regions located within the semiconductor substrate and separated by the channel, where a portion or the gate dielectric interposed between the spacer and the semiconductor substrate is thicker than a portion of the gate dielectric interposed between the gate electrode and the semiconductor substrate.

13. The semiconductor structure of claim 12 wherein the spacer is located completely upon the gate dielectric.

14. The semiconductor structure of claim 12 wherein the spacer is also located upon an additional layer that laterally abuts the gate dielectric.

15. The semiconductor structure of claim 12 wherein the gate dielectric is also located interposed between the gate electrode and the spacer.

16. A method for fabricating a semiconductor structure comprising
providing a semiconductor structure including:
a semiconductor substrate;
a dummy gate dielectric located upon the semiconductor substrate;
a dummy gate electrode located upon the dummy gate dielectric and over a channel region within the semiconductor substrate;
a spacer located adjacent a sidewall of the dummy gate electrode and also upon the dummy gate dielectric; and
a plurality of source and drain regions located within the semiconductor substrate and separated by the channel;
etching the dummy gate electrode from the semiconductor structure to expose the dummy gate dielectric;
etching the dummy gate dielectric to expose the channel region and form a void at least in-part undercut beneath the spacer;
forming a gate dielectric upon the channel region and filling the void; and
forming a gate electrode upon the gate dielectric.

17. The method of claim 16 wherein the etching the dummy gate dielectric provides the void partially undercut beneath the spacer.

18. The method of claim 16 wherein the etching the dummy gate dielectric provides the void fully undercut beneath the spacer.

19. The method of claim 16 wherein the forming the gate dielectric and the forming the gate electrode provide that a sidewall of the gate electrode contacts the gate dielectric.

20. The method of claim 16 wherein the forming the gate dielectric and the forming the gate electrode provide that the gate dielectric has a dielectric constant greater than about 7 and the gate electrode comprises a metal gate material.
